(19) United States
(12) Patent Application Publication
(10) Pub. No.: US 2009/0263641 A1
(43) Pub. Date: Oct. 22, 2009

(54) METHOD AND APPARATUS TO COAT OBJECTS WITH PARYLENE

(75) Inventors: Sidney Edward Martin, III, Fairhaven, MA (US); Eric Roger Dawicki, Fairhaven, MA (US); Angela Michele Dawicki, Fairhaven, MA (US)

Correspondence Address: WOLF GREENFIELD & SACKS, P.C., 600 ATLANTIC AVENUE, BOSTON, MA, 02210-2206, US

(73) Assignee: Northeast Maritime Institute, Inc., Fairhaven, MA (US)

(21) Appl. No.: 12/104,152

(22) Filed: Apr. 16, 2008

(51) Int. Cl. B32B 27/06; C23C 16/02; B32B 9/04; B32B 15/04; B32B 27/00

(52) U.S. Cl. 428/221; 427/255.6; 428/411.1; 428/457; 118/719; 428/422; 428/473.5; 428/446; 428/698; 428/702

(57) ABSTRACT

The present invention provides a novel method to apply Silquest to an object as a vapor, a related method to coat objects with Parylene and Silquest, and objects coated by these methods. The invention further provides an vapor deposition apparatus with multi-temperature zone furnaces that is useful for applying a Parylene coating to objects. The invention further provides objects coated with Silquest and polymers, including Parylene, where the objects are incompatible with immersion in water.

This application claims priority to Provisional Patent Application Ser. No. ______, filed Sep. 5, 2007 (formerly U.S. patent application Ser. No. 11/850,134), Provisional Patent Application Ser. No. ______, filed Oct. 23, 2007 (formerly U.S. patent application Ser. No. 11/876,977) and Provisional Patent Application Ser. No. ______, filed Oct. 23, 2007 (formerly U.S. patent application Ser. No. 11/876,998), the contents of each prior application incorporated herein by reference.

### BACKGROUND

Parylene conformation coatings are ultra-thin, pinhole-free polymer coatings that are commonly used to protect medical devices, electronics, and products from the automotive, military and aerospace industries. Chemical vapor deposition at low pressure produces the thin, even conformational polymer coating. The resulting Parylene coating has a very high electrical resistively and resists moisture penetration.

Parylene is the generic name for members of a unique polymer series. The basic member of the series, called Parylene N, is poly-para-xylylene, a polymer manufactured from di-p-xylylene ([2,2]paracyclophane). Parylene N is a completely linear, highly crystalline material. Parylene C, the second commercially available member of the series, is produced from the same monomer modified only by the substitution of a chlorine atom for one of the aromatic hydrogens. Parylene D, the third member of the series, is produced from the same monomer modified by the substitution of the chlorine atom for two of the aromatic hydrogens. Parylene D is similar in properties to Parylene C with the added ability to withstand higher use temperatures. See FIG. 1A-C.

The adhesion of Parylene to a wide variety of objects can be improved by pre-treating the object with an organic silane prior to Parylene coating. Silane treatment forms radicals on the surface of the object to which Parylene can bond. Two silanes, vinyl trichlorosilane in either xylene, isopropanyl alcohol, or Freon®, and gamma-methacryloxypropyltrimethoxy Silane (Silquest® A-174 or Silquest® A-174(NT)) in a methanol-water solvent have been used for this purpose. However, electronics components cannot tolerate electrical paths that are developed either by direct contact with a liquid that allows conduction of electricity, nor are they compatible with the ion residue often left after the evaporation of water or the liquid in which it was immersed. Even if there is no immediate growth, dendritic conductors may grow later on due to the voltage potential between conductors on the electronics component. These short circuits caused by the conductive fluids and dendrites can drain batteries and allow high currents to flow in areas in which they were was not intended. Often, the components of electronic equipment, such as circuit boards, must be silane and Parylene coated separately, and then assembled to remain functional.

The Parylene deposition process is generally carried out in a closed system under negative pressure. Parylene polymers are deposited from the vapor phase by a process that resembles vacuum metallizing, however, the Parylenes are formed at around 0.1 Torr. The first step is the vaporization of the solid Parylene dimer at approximately 150 degrees C. in the vaporization chamber. The second step is the quantitative cleavage (pyrolysis) of the dimer at the two methylene-methylene bonds at about 680 degrees C. in the pyrolysis chamber to yield the stable monomer diradical, para-xylylene. Finally, the monomer in gas form enters the room temperature deposition chamber where it simultaneously absorbs and polymerizes on the object to be coated. The closed system generally has separate chambers for the vaporization, pyrolysis and deposition of the Parylene, with the chambers being connected with the appropriate plumbing or tubular connections.

Apparatus for chemical vapor deposition of Parylene onto objects are known in the art. See for example, U.S. Pat. Nos. 4,945,856, 5,078,091, 5,268,033, 5,488,833, 5,534,068, 5,536,319, 5,536,321, 5,536,322, 5,538,758, 5,556,473, 5,641,358, 5,709,753, 6,406,544, 6,737,224, 6,406,544, all of which are incorporated by reference herein.

What is needed are improved apparatus and methods to coat objects with Parylene that are will broaden the range of objects that may be coated as well as improve ease and efficiency of the process.

### BRIEF SUMMARY OF THE INVENTION

One embodiment of the invention provides a method to apply a coating of Parylene to object, which may comprise the steps of: (A.) vaporizing Parylene dimer by heating it to 150-200 degrees C. to form gaseous Parylene dimers; (B.) cleaving gaseous Parylene dimers to gaseous Parylene monomers by heating gaseous Parylene dimers to 650 to 700 degrees C.; (C.) vaporizing Silquest® by heating it to its evaporation point to form gaseous Silquest®; (D.) contacting object to be coated with Parylene with the gaseous Silquest® of Step C; and (E.) contacting object to be coated with Parylene with the gaseous Parylene monomers of Step B for sufficient time to deposit coat of Parylene of a final thickness. In some embodiments, the Parylene may be selected from a group consisting of Parylene D, Parylene C, Parylene N, Parylene HT®, and a Parylene derived from Parylene N, and may preferably be Parylene C. In some embodiments, the Silquest® may be Silquest® A-174, Silquest® 111 or Silquest® A-174(NT), and may preferably be Silquest® A-174.

In some embodiments, in Step A, the Parylene dimer may be vaporized by heating in two or more stages, and preferably in two stages of about 170 degrees C., and about 200 degrees C. to about 220 degrees C. In some embodiments, in Step B, the Parylene dimer may be cleaved by heating in two or more stages, and preferably in two stages of about 680 degrees C. and to more than about 700 degrees C. In some embodiments, in Step C, the Silquest® may be vaporized in a 50:50 solution with water. In other embodiments, in Step C the Silquest® may be vaporized at 80 degrees C. for about 2 hours. In some embodiments, the final thickness of the Parylene coat may be from about 100 Angstrom to about 3.0 mm.

In some embodiments, the object to be coated with Parylene may be incompatible with immersion in water, such as electronics equipment, paper, textiles, ceramics, plastics, frozen liquids, batteries, speakers, solid fuel, medical devices, paper, and space suits. Some embodiments provide an object coated by this method.

A second embodiment of the invention is a method to coat objects with Silquest, which may have the steps: (A.) vaporizing Silquest® by heating it to its evaporation point to form gaseous Silquest®; and (B.) contacting object to be coated with Parylene with the gaseous Silquest® of Step A. In some embodiments, the Silquest® may be Silquest® A-174, Silquest® 111 or Silquest® A-174(NT), and may be preferable Silquest® A-174. In some embodiments, in Step A, the Silquest® may be vaporized in a 50:50 solution with water. In some embodiments, in Step A, the Silquest® may be vaporized at 80 degrees C. for about 2 hours. In some embodiments, the object to be coated with Parylene may be incompatible with immersion in water, such as electronics equipment, paper, textiles, ceramics, plastics, frozen liquids, batteries, speakers, solid fuel, medical devices, paper, and space suits. The invention may also provide an object coated by this method.

A third embodiment of the invention provides a polymer-coated object which may be coated with Silquest® and with at least one polymer, where the object may be incompatible with immersion in water. In some embodiments, the uncoated object may become at least partially non-functional after immersion in water and subsequent drying, such as an electronics component. In other embodiments, the uncoated object may be degraded upon immersion in water, such as metal, paper or textile. In some embodiments, the polymer may be polynaphtahlene (1,4-napthalene), diamine (O-tolidine), polytetrafluoroethylene (Teflon®), polyimides, silicas (SiO₂), titania (TiO₂), aluminum nitride (AlN), lanthanum hexaboride (LaB₆), Parylene D, Parylene C, Parylene N, Parylene HT®, or a Parylene derived from Parylene N, and may be preferably Parylene C. In some embodiments, the Silquest® may be Silquest® A-174, Silquest® 111 or Silquest® A-174(NT), and may be preferably Silquest® A-174. In some embodiments, the polymer coating may be on the inside and outside of the object, and in particular, the polymer coating on the outside of the object may be continuous with the polymer coating on the inside of the object.

A fourth embodiment of the invention provides an apparatus to apply a coating of Parylene, which includes a vaporization chamber with a plurality of temperature zones; operably linked to a pyrolysis chamber; operably linked to a vacuum chamber. In some embodiments, the vacuum chamber may include a deposition chamber operably linked to the pyrolysis chamber and a vacuum means, and the vacuum means may be one or more vacuum pumps. In some embodiments, the vaporization chamber may have a plurality of temperature zones, preferably two temperature zones. In other embodiments, the pyrolysis chamber may have a plurality of temperature zones, preferably two temperature zones. In some embodiments, the vaporization chamber and/or the pyrolysis chamber may be a tubular furnace.

### BRIEF DESCRIPTION OF DRAWINGS

Further advantages of the present invention may be understood by referring to the following descriptions taken in conjunction with the accompanying drawing, in which:

FIG. 1 is are diagrams of the chemical structures of varieties of Parylene and Silquest®. FIG. 1A is a diagram of Parylene N. FIG. 1B is a diagram of Parylene C. FIG. 1C is a diagram of Parylene D. FIG. 1D is a diagram of Parylene HT®. FIG. 1E is a diagram of Silquest® A-174 (also known as Silquest® A-174(NT)).

FIG. 2 is a schematic diagram of one embodiment of the apparatus for chemical vapor deposition of Parylene of the invention.

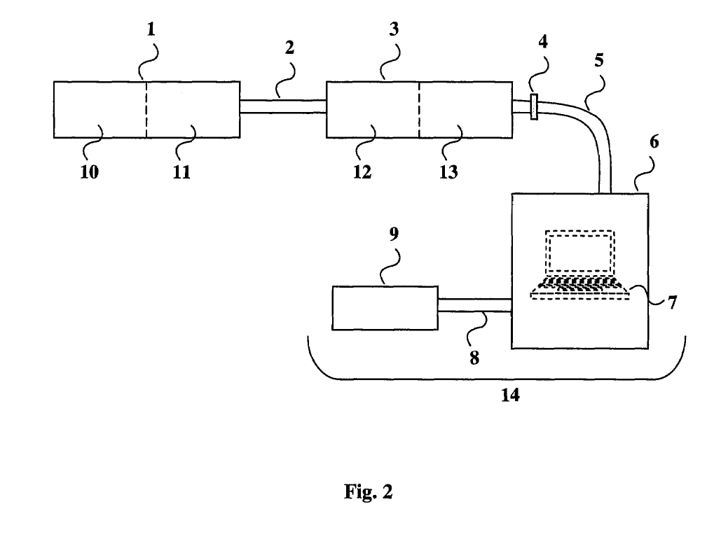

### DETAILED DESCRIPTION

It is to be understood that the figures and descriptions of the present invention have been simplified to illustrate elements that are relevant for a clear understanding of the present invention, while eliminating, for purposes of clarity, other elements of a conventional Parylene coating method or apparatus. For example, certain Parylene coating systems may include multiple deposition chambers, valves or vacuum pumps, that are not described herein. Those of ordinary skill in the art will recognize, however, that these and other elements may be desirable in a typical Parylene coating system. However, because such elements are well known in the art and because they do not facilitate a better understanding of the present invention, a discussion of such elements is not provided herein.

Also, in the claims appended hereto, any element expressed as a means for performing a specified function is to encompass any way of performing that function including, for example, a combination of elements that perform that function. Furthermore the invention, as defined by such means-plus-function claims, resides in the fact that the functionalities provided by the various recited means are combined and brought together in a manner as defined by the appended claims. Therefore, any means that can provide such functionalities may be considered equivalents to the means shown herein.

For the purposes of this specification, unless otherwise indicated, all numbers expressing quantities of ingredients, time, temperature, thickness of coats, and other properties or parameters used in the specification are to be understood as being modified in all instances by the term “about.” Accordingly, unless otherwise indicated, it should be understood that the numerical parameters set forth in the following specification and attached claims are approximations. At the very least, and not as an attempt to limit the application of the doctrine of equivalents to the scope of the claims, numerical parameters should be read in light of the number of reported significant digits and the application of ordinary rounding techniques.

Additionally, while the numerical ranges and parameters setting forth the broad scope of the invention are approximations as discussed above, the numerical values set forth in the Examples section are reported as precisely as possible. It should be understood, however, that such numerical values inherently contains certain errors resulting from the measurement equipment and/or measurement technique.

Any patent, publication, or other disclosure material, in whole or in part, that is said to be incorporated by reference herein is incorporated herein only to the extent that the incorporated material does not conflict with the existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements or other disclosure material set forth herein will only be incorporated to the extent that no conflict arises between the incorporated material and the existing disclosure material.

The present inventions relate to novel methods and apparatus to coat objects with Parylene and/or Silquest®, as well as objects coated by the methods, and an apparatus to coat objects with polymers, and novel polymer coated objects. Many objects require prior treatment to make the surfaces of the object more amenable to the adherence of a polymer, such as by applying a silane-containing coating. Currently, methods entail immersing the object in a dilute solution of organic silane, then removing the object from the silane-solution and allowing the object to dry. The present invention uses an improved method of applying a silane-containing coating to an object which may be used on objects that are destroyed by submersion in a solution, such as electronics devices.

In the method of the invention, a silane-containing coating is applied in a vapor phase to the object to be Parylene coated. This allows objects that are incompatible with immersion, and thus previously unsuitable for Parylene coating, to be coated with Parylene. Now, for example, electronics equipment does not have to be disassembled, coated and then reassembled, but with the method of the invention, may be coated in its “off-the-shelf” state. The method of the invention may apply a coating of Parylene both to the circuit board inside the electronic device as well as the outside surface of the electronic device in one process. The method of the invention may be used to particular advantage with off-the-shelf electronics equipment. The method of the invention may also be very useful to improve the ease and efficiency by which many other objects are Parylene coated.

The coating process of the invention may be used on products used in the commercial marine, recreational boating, military (aerospace and defense), industrial and medical industries, as well as others. The coating process is specifically designed to “seal” the devices, which protects those types of devices commonly used in marine and hazardous environments against operational malfunction caused by exposure to moisture, immersion in water, dust, effects of high wind and chemicals. The coating may enhance the survivability and sustainability of operational equipment and high value specialty products susceptible to corrosion and degradation.

The method may apply a uniform, thin layer of Parylene coating within a vacuum chamber at 25 degrees C. using standard chemical vapor deposition practices, and may be applied in thicknesses ranging from 0.01 to 3.0 millimeters, depending on the item coated. The item once coated may be weatherproof and water resistant, and may withstand exposure to extreme weather conditions and exposure to most chemicals. Any solid surface may be coated, including plastics, metals, woods, paper and textiles. Sample applications include, but are not limited to: electronics equipment, such as cell phones, radios, circuit boards and speakers; equipment used in ocean and space exploration, or oil rig operations; hazardous waste transportation equipment; medical instruments; paper products; and textiles.

The method of the invention to coat objects with Silquest® may include the following several steps:
A. vaporizing a Parylene dimer form by heating to 150-200 degrees C. to form gaseous Parylene dimers;
B. cleaving gaseous Parylene dimers to gaseous Parylene monomers by heating gaseous Parylene dimers to about 650 to about 700 degrees C.;
C. vaporizing Silquest® A-174 by heating it to its evaporation point to form gaseous Silquest® A-174;
D. contacting an object to be coated with gaseous Silquest® A-174; and
E. contacting the object to be coated with gaseous Parylene monomers for sufficient time to deposit a coat of Parylene of a final thickness.

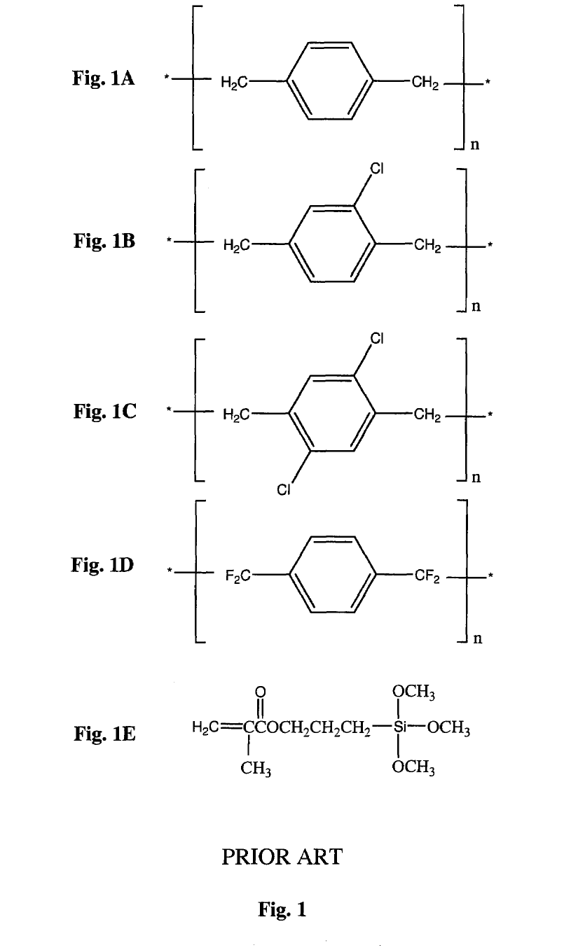

Steps A, B and E of the method to coat objects with Parylene may be performed by any manner that is currently in use for the coating of objects with Parylene, as will be well-known to those of ordinary skill in the art. Further, any of the steps of the invention may be performed in an order different that than the one presented. For example, Step D may be performed prior to Step A. Further, some steps may be performed simultaneously with other steps: for example, Step D may be performed simultaneously with Step A. In preferred embodiments, Parylene C may be used. See FIG. 1B. In other embodiments, other forms of Parylene may be used, including but not limited to, Parylene N, Parylene D and Parylene HT®. See FIGS. 1A, 1B and 1D. In some embodiments, the Parylene may be derived from Parylene N, or poly-para-xylylene, by the substitution of various chemical moieties. In preferred embodiments, the Parylene may form completely linear, highly crystalline material. In the Example, one embodiment of the method is set forth with a more detailed description on how the steps of the method may be performed.

In some embodiments, Step A, vaporizing Parylene dimer form by heating to 150-200 degrees C. to form gaseous Parylene dimers, may be performed in a furnace chamber. In preferred embodiments, the Parylene dimer is heated in stages to the desired 150-200 degrees C. In some embodiments, this staged heating of the Parylene dimer takes place in a furnace chamber that is multi-zoned, allowing for different temperature set points in different zones of the furnace chamber While not limiting the method of action of this staged heating procedure, it is thought that the method allows the Parylene to be uniformly “cracked” as a monomer and allow better control of the thickness of the final Parylene coating on the object, as it will remain a monomer longer in the deposition chamber so that it can spread throughout the deposition chamber. In some embodiments, the Parylene dimer is vaporized by heating in 2 stages, 3 stages, 4 stages, or more than 4 stages. In some embodiments, the temperatures of the stages are about 170 degrees C., and about 200 to about 220 degrees C. While not limiting the invention to a theory, the inventors believe in the first stage of vaporization, the Parylene will be vaporized, and in the second stage the vapor will be preheated to that when it enters the pyrolization chamber, it will be cleaved into a monomer at a higher rare.

In some embodiments, Step B, cleaving gaseous Parylene dimers to gaseous Parylene monomers by heating gaseous Parylene dimers to 650 to 700 degrees C., may be performed in a furnace chamber. In preferred embodiments, the gaseous Parylene dimer is heated in stages to the desired 650 to 700 degrees C. In some embodiments, this staged heating of the gaseous Parylene dimer takes place in a furnace chamber that is multi-zoned, allowing for different temperature set points in different zones of the furnace chamber. In some embodiments, the Parylene dimer is cleaved to monomers by heating in 2 stages, 3 stages, 4 stages, or more than 4 stages. In some embodiments, the temperatures of the stages are about 680 degrees C. and more than about 700 degrees C. While not limiting the invention to theory, it is thought that in the first stage of heating, the gaseous Parylene dimers will be cleaved into a monomers, and in the second state of heating, the gaseous monomers will be heated further to above about 700 degrees C. to assure that the gaseous monomers are in the deposition chamber longer so as to fill it more evenly.

The method of the invention utilizes a step in which gaseous Silquest® A-174 (FIG. 1E) may be brought into contact with the object to be coated (Step D). This step is particularly advantageous to aid the Parylene coating hydrophilic surfaces of objects. In some embodiments, Silquest® 111 or Silquest® A-174(NT) is substituted for Silquest® A-174 throughout the method to coat objects with Parylene of the invention. In one embodiment, the object may be contacted with the gaseous Silquest® A-174 in a vacuum chamber.

In Step C, the Silquest® A-174 may be vaporized by heating it to its evaporation point. In preferred embodiments, this step may be performed prior to contacting the object to be coated with the gaseous Silquest® A-174. In one embodiment, this step may be preformed by placing the Silquest® into a crucible, inserting the crucible into a 2″ thermocouple onto a hot place in the vacuum chamber containing the object to be coated. The amount of Silquest® poured into the crucible may depend on the number and size of objects in the vacuum chamber. In various embodiments, the amount of Silquest® vaporized may range from about 10 to about 100 ml, or in some cases more. In one embodiment, the hot plate may heat the Silquest® to its evaporation point. In other embodiments, other methods to heat the Silquest® to its evaporation point may be used, as will be well-known to those of ordinary skill in the art. In another embodiment, a mixture of Silquest® A-174 with distilled water may be vaporized. In one embodiment, a 50/50 mix of Silquest® and distilled water is heated until the Silquest® is vaporized, which may be at about 80 degrees C. for about 2 hours.

While in preferred embodiments, the object may be coated with Silquest® and then Parylene in the same vacuum chamber, in other embodiments, the two coatings may be applied in different chambers, and/or at different times. In a preferred embodiment, once the exposure of the object to the evaporated Silquest® is complete, the chamber may be put under a vacuum, and the Parylene deposition may start as soon as a suitable vacuum is reached. It may be preferable to completely exhaust the Silquest® vapor from the chamber before introducing the gaseous Parylene monomers. The period of time between the application of the Silquest® coating and the Parylene coating may be, in various embodiments, from about 0 minutes to about 120 minutes. The temperature of the evaporation point of Silquest® A-174 is about 80 degrees C. While not limiting the mechanism of action of the Silquest®, it is thought that the vaporized Silquest® coats the object, increasing the ability of the surface to accept the Parylene monomer gas by causing the surface to have free radical sites to which the Parylene monomers will bond.

In Step D, the object to be coated may be contacted with gaseous Silquest® A-174. In preferred embodiments, this contacting may be done in the same deposition chamber that will later be used to contact the gaseous Parylene monomers to the object. In some embodiments, the object is contacted with the gaseous Silquest® for a time of about 2 hours.

The objects to be coated by this method may be any object that has a solid surface at the temperature at which the object is contacted with Silquest® and Parylene. Such objects include, but are not limited to, electronics equipment, cameras, circuit boards, computer chips, paper, textiles, ceramics, plastics, frozen liquids, batteries, speakers, solid fuel, medical devices, paper, and hazardous waste transportation equipment, hazardous waste, medical instruments, equipment used in ocean and space exploration, space suits. In preferred embodiments, the objects are those which are incompatible to submersion in water, including but not limited to, off-the-shelf electronics components, such as laptop computers, cameras, radios and cell phones. In other embodiments, the objects may be degraded upon submersion in water, such as but not limited to, metal screws and other hardware, paper products and textiles. In other embodiments, the objects may be those which require flexibility to be functional, such as audio speakers. In further embodiments, the objects may be those which are desired to be protected from oxygen, such as but not limited to, fuel cells, weapons cartridges and ammunition. In further embodiments, the objects may be those which must be isolated from the environment, such as hazardous waste products. In further embodiments, the objects may be those which require protection from chemical exposure, such as but not limited to, hazardous waste transportation equipment.

In Step E, the object to be coated may be contacted with gaseous Parylene monomers for sufficient time to deposit coat of Parylene. In preferred embodiments, this step may be performed in a deposition chamber, and particularly preferably in the same deposition chamber in which the object was contacted with Silquest®. In other preferred embodiments, the deposition chamber and the objects to be coated may be at room temperature. In some embodiments, the deposition temperature may be about 5 to about 30 degrees C., preferably about 20 to about 25 degrees C. In some embodiments, the deposition chamber may be refrigerated to speed up the deposition process.

In some embodiments, the length of time that the object may be contacted with the gaseous Parylene monomers may be varied to control the final thickness of the Parylene coat on the object. In various embodiments, the final thickness of the Parylene coating may be between about 100 Angstrom to about 3.0 millimeters. In preferred embodiments, the final thickness of the Parylene coating may be between about 0.5 millimeters to about 3.0 millimeters. In general, a deposition time from about 8 hours to about 18 hours may be used to achieve a Parylene coat thickness of about 0.002 inches, depending on the temperature of the deposition chamber. The choice of final thickness of Parylene coating may depend to some degree on the object to be coated and the final use of the object. Thinner final coats may be desirable for objects that require some movement to be functional, such as power buttons. Thicker coatings may be desirable for objects that will be submerged in water.

Another embodiment of the invention are the objects coated with Parylene by the method of the invention.

Another embodiment of the invention provides a novel method to coat objects with Silquest®. This method contains the following steps:
A. vaporizing Silquest® A-174 by heating it to its evaporation point to form gaseous Silquest® A-174; and
B. contacting an object to be coated with gaseous Silquest® A-174.

In Step A, the Silquest® A-174 may be vaporized by heating it to its evaporation point. In some embodiments, Silquest® 111 or Silquest® 174(NT) is substituted for Silquest® A-174 throughout the method. In preferred embodiments, this step may be performed prior to contacting the object to be coated with the gaseous Silquest® A-174. In one embodiment, this step may be performed by placing the Silquest® into a crucible, inserting the crucible into a 2″ thermocouple onto a hot place in the vacuum chamber containing the object to be coated. The amount of Silquest® poured into the crucible may depend on the number and size of items in the vacuum chamber. In various embodiments, the amount of Silquest® vaporized may range from about 10 to about 100 ml, or in some cases more. In one embodiment, the hot plate may heat the Silquest® to its evaporation point. In other embodiments, other methods to heat the Silquest® to its evaporation point may be used, as will be well known to those of ordinary skill in the art. In another embodiment, a mixture of Silquest® A-174 with distilled water may be vaporized. In one embodiment, a 50/50 mix of Silquest and distilled water may be heated until the Silquest is vaporized, which may be at about 80 degrees C. for about 2 hours.

In Step B, the object to be coated may be contacted with gaseous Silquest® A-174. In some embodiments, the object is contacted with the gaseous Silquest® for a time of about 2 hours.

The objects to be coated by this method may be any object that has a solid surface at the temperature at which the object is contacted with Silquest®. Such objects include, but are not limited to, electronics equipment, cameras, circuit boards, paper, textiles, ceramics, plastics, frozen liquids, batteries, speakers, solid fuel, medical devices, paper, and hazardous waste transportation equipment, hazardous waste, medical instruments, equipment used in ocean and space exploration, space suits. In preferred embodiments, the objects are those which are incompatible to immersion in water when uncoated, including but not limited to, off-the-shelf electronics components, such as laptop computers, cameras, radios and cell phones. In other embodiments, the objects may be degraded upon immersion in water when uncoated, such as but not limited to, metal screws and other hardware, paper products and textiles.

Another embodiment of the invention provides objects coated with at least one polymer and Silquest® where the uncoated objects may be incompatible with immersion in water. Uncoated objects that are incompatible with immersion in water may be those which partially or totally lose functionality after immersion in water. In preferred embodiments, the objects may be those which when uncoated become at least partially non-functional after immersion in water and subsequent drying, including but not limited to, off-the-shelf electronics components, such as laptop computers, radios and cell phones. In other embodiments, the objects may be those which when uncoated may be degraded upon submersion in water, such as but not limited to, metal screws and other hardware, paper products and textiles.

Polymers of interest include, but are not limited to, polynaphtahlene (1,4-napthalene), diamine (O-tolidine), polytetrafluoroethylene (Teflon®), polyimides, silicas (SiO₂), titania (TiO₂), aluminum nitride (AlN), and lanthanum hexaboride (LaB₆). These polymers may be applied by standard techniques, as will be well known to those of ordinary skill in the art. In preferred embodiments, Parylene C may be used. In other embodiments, other forms of Parylene may be used, including but not limited to, Parylene N, Parylene D and Parylene HT®. In some embodiments, the Parylene may be derived from Parylene N, or poly-para-xylylene, by the substitution of various chemical moieties. In preferred embodiments, the Parylene may form completely linear, highly crystalline material.

The objects coated with at least one polymer and Silquest® may have a polymer coating on the outside of the object, as well on the inside of the object if there are gaps in the outer surface of the object that allow the Silquest® and the polymer gases admission to the inside of the object. In a preferred embodiment, the outside coating of the polymer is continuous with the inside coating of polymer. For example, an electronics device such as a cell phone may have a coat of Parylene on the circuit boards and battery within the device as well as on the keyboard and screen of the cell phone.

The coating methods and coated objects may be particularly suited for the use in the harsh environmental conditions encountered by the military. In some embodiments, the object coated with may meet the applicable requirements of military specifications MIL-PRF-38534, the general performance requirements for hybrid microcircuits, Multi-Chip Modules (MCM) and similar devices. In some embodiments, the Parylene-coated object may meet the applicable requirement of military specifications MIL-PRF-38535, the general performance requirements for integrated circuits or microcircuits. In some embodiments, the Parylene-coated object may meet the applicable requirements of both military specifications MIL-PRF-38534 and MIL-PRF-38535.

Another embodiment of the invention is an apparatus for the chemical vapor deposition of Parylene which may comprise an improved vaporization chamber and/or pyrolysis chamber. While this apparatus may be particularly useful for the chemical vapor deposition of Parylene, is may also be used to vapor deposit other chemicals, including but not limited to, polynaphtahlene (1,4-napthalene), diamine (O-tolidine), polytetrafluoroethylene (Teflon®), polyimides, silicas (SiO₂), titania (TiO₂), aluminum nitride (AlN), and lanthanum hexaboride (LaB₆), and others that will be well-known to those in the art. The apparatus of the invention may improve upon previous chemical vapor deposition apparatus by providing a vaporization chamber and/or a pyrolysis chamber with a plurality of temperature zones. While not limiting the operation of the apparatus, it is thought that by allowing different temperature set points within each chamber, the rate of heating of Parylene is improved. The multi-zoned vaporization and pyrolysis chambers may allow the Parylene to be uniformly cleaved into a monomer, and allow better control of the final thickness of the Parylene coat on the object. The Parylene may remain a monomer longer in the deposition chamber so that it can be better spread throughout the deposition chamber.

FIG. 1 shows a Parylene coating apparatus according to one embodiment of the present invention. The vaporization chamber 1 may have two temperature zones 10 and 11. The pyrolysis chamber 3 also may have two temperature zones 12 and 13. The vaporization chamber 1 may be operably linked to the pyrolysis chamber 3 by a component 2 that may be capable of communicating gas from the vaporization chamber 1 to the pyrolysis chamber 3. The pyrolysis chamber 3 may be operably linked to the vacuum chamber 14, which may comprise a deposition chamber 6 and may be operably linked to a vacuum means 9 by a component 8 which may be capable of pulling a vacuum on the deposition chamber 6. The component 5 operably linking the pyrolysis chamber 3 to the vacuum chamber 14 may be capable of communicating gas from the pyrolysis chamber 3 to the vacuum chamber 14, and also may include a valve 4 that is capable of regulating the flow of gas from the pyrolysis chamber 3 to the vacuum system 14.

The vaporization chamber 1 may be any furnace/heating system that is capable of heating a solid to about 150 to about 200 degrees C. In preferred embodiments, the vaporization chamber is capable of heating a gas to 1200 degrees C. In some embodiments, the vaporization chamber 1 may be capable of containing gases. The vaporization chamber 1 may also be capable of generating zones within its heating chamber that are different temperatures. Finally, the vaporization chamber 1 may be capable of maintaining a high vacuum. In preferred embodiments, the vaporization chamber may support a vacuum of at least about 0.1 Torr.

The vaporization chamber 1 may be operably linked to the pyrolysis chamber 3 by many components that will be well known to those of ordinary skill in the art. The operable connection between the vaporization chamber 1 and pyrolysis chamber 3 may be, in some embodiments, a connection that allows gas to pass from the vaporization chamber 1 to the pyrolysis chamber. In some embodiments, this component 2 may be a glass tube, a retort, or a metal tube, among others. In other embodiments, this component 2 may also contain valves, temperature sensors, other sensors, and other conventional components, as will be well know to those in the art.

The pyrolysis chamber 3 may be any furnace/heating system that is capable of heating a gas to about 650 to about 700 degrees C. In some embodiments, the pyrolysis chamber 3 may be capable of containing gases. In some embodiments, the pyrolysis chamber 3 may be capable of generating zones within its heating chamber that are different temperatures. Finally, in some embodiments, the pyrolysis chamber 3 may be capable of maintain a high vacuum. In preferred embodiments, the vaporization chamber may support a vacuum of at least about 0.1 Torr.

The vaporization chamber and the pyrolysis chamber, in general, may be furnaces capable of generating two or more temperature zones within their chamber. In a preferred embodiment, the furnace has two temperature zones. In some embodiments, the temperature zones are situated in the furnace chamber such that a gas will move sequentially through the temperature zones before exiting the furnace. Preferably, the furnace may have a maximum temperature of 1200 degrees C. In a preferred embodiment, the furnace is a tubular furnace. In other embodiments, the furnace may have a glass retort. The specific parameters of one embodiment of a two-zoned furnace suitable to be used as the vaporization chamber and/or the pyrolysis chamber may be found in Example 2.

The pyrolysis chamber 3 may be operably linked to the vacuum system 14 by many components that will be well known to those of ordinary skill in the art. The operable connection between the pyrolysis chamber 3 and the vacuum system 14 may be, in some embodiments, a connection that allows gas to pass from the pyrolysis chamber 3 to the vacuum system 14. In some embodiments, this component 5 may be a glass tube, a retort, or a metal tube, among others. In other embodiments, this component 5 may contain valves, temperature sensors, other sensors, and other conventional components, as will be well know to those in the art. In a preferred embodiment, component 5 may contain one or more valves 4 by which the flow of gas through the component 5 may be regulated.

The vacuum system 14 may contain a deposition chamber 6 which may be operably connected 8 to a vacuum means 9. In some embodiments, the operable connector 8 may be capable of holding a vacuum up to at least about 0.05 Torr, and preferably at least about 1×10⁻⁴ Torr. In other embodiments, the vacuum means 9 may be one or more vacuum pumps, which may be capable of pulling a vacuum on the deposition chamber of at least about 0.05 Torr, and preferably at least about 1×10⁻⁴ Torr. In some embodiments, the deposition chamber 6 may be of sufficient size to contain the object to be coated 7. In other embodiments, the deposition chamber 6 may be capable of holding an vacuum of at least about 0.05 Torr, and preferably at least about 1×10⁻⁴ Torr range.

### EXAMPLES

### Example 1

This example describes one embodiment of the method and apparatus used to coat an object with Parylene. This embodiment uses Parylene C.

### Coating Process

The apparatus consists of two sections: (1) a furnace/heating section; and (2) a vacuum section. The furnace section is made up of two furnaces which are connected by glass tubes referred to as retorts. The furnace and vacuum sections are connected by valves that allow gas flow between the furnace and vacuum sections.

The furnace portion of the equipment is produced to custom design to meet NMI's specifications and requirements by Mellen Furnace Co. (Concord, N.H.). See Example 2. The vacuum portion is produced to custom design by Laco Technologies Inc. (Salt Lake City, Utah).

The process to coat items with Parylene is as follows:

(1) First Furnace Chamber. Parylene C in Dimer form (two molecule form) in an amount sufficient to coat the item is placed in the furnace chamber. The items are coated in a thickness ranging from 0.01 to 3.0 mms. The Parylene C is placed in a stainless steel “boat” (a standard container made out of metal or glass) that is inserted into the furnace through a vacuum secured opening of the tube (the boat is pushed with a rod into the furnace). The opening is sealed after inserting the Parylene C. The furnace is then brought to 150-200 degrees C. to create an environment in which the solid Parylene C becomes a gas. The gas is held in the first furnace chamber until two valves open. The first of two valves will not open until the cold traps in the vacuum section are filled with liquid nitrogen (LN2) and the traps are “cold”. The LN2 is purchased from a local supply house. The LN2 is placed into a one gallon container at the supplier. The LN2 is poured from the container into the “trap.” The second valve is variable and is opened when the gas is pulled from the first furnace by vacuum.

(2) Second Furnace Chamber. The Parylene C gas moves to the second furnace which is a temperature of 650 to 700 degrees C. The heat in this furnace causes the Parylene C gas to separate into individual molecules (monomers). The gas in monomer form is then pulled by vacuum into the deposition chamber.

(3) Vacuum Chamber. The vacuum portion of the machine consists of a deposition chamber with two vacuum pumps. The first vacuum pump is a “roughing” pump which pulls down the initial vacuum. The initial pressure is in the 1×10⁻³ Torr range. The second stage pump then pulls down to the final pressure in the 1×10⁻⁴ Torr range. The vacuum pumps are protected by liquid nitrogen traps that protect the pumps from the solidification of the monomer gas by condensing the gas on the cold trap surface.

The items to be coated are set on shelves in the deposition chamber prior to starting the coating process. The devices to be coated are masked (with workmanlike methods) in those areas on and within the device that are not to be coated. The masking is done in areas where electrical or mechanical connectivity must remain. The material is coated onto the item at room temperature (75 degrees Fahrenheit).

Inside the vacuum chamber there is a crucible of Silquest® A-174 (Momentive Performance Materials Inc., Wilton, Conn.) that is poured into a ceramic crucible. The crucible is inserted into a 2 inch thermocouple onto a hot plate in the vacuum chamber. The amount of Silquest® A-174 poured depends on the amount of items in the chamber, but is between 10-100 ml. The plate heats the Silquest® A-174 to an evaporation point such that it coats the entire area inside the chamber, included any objects within the chamber.

Once the Silquest vapor is evacuated from the deposition chamber, the monomer gas is pulled by the lower vacuum in the vacuum chamber. When the gas is pulled into the chamber it is deflected so that it sprays within the entire area of the chamber. The items are coated as the monomer gas cools. The gas cools from 600 degrees C. to 25 degrees C. and hardens on the device within the chamber. During that cooling process, the monomers deposit on the surface of the item to be coated creating a polymer three dimensional chain that is uniform and pin hole free. The deposition equipment controls the coating rate and ultimate thickness. The required thickness of a Parylene coating is determined by time exposed to the monomer gas. The thickness can range from hundreds of angstroms to several millimeters.

### Example 2

This example gives the specifications of one embodiment of the zoned furnace that may be used in the apparatus to apply a coating of Parylene of the invention. This furnace assembly was made by the Mellen Company, Inc., Concord N.H.

One Mellen Model TV12,

Single or two zoned—solid tubular furnace is capable of operation at temperatures up to 1200 degrees C. in air. The furnace utilizes the Mellen standard Series 12V heating elements (exposed Fe—Cr—Al windings within a special designed holder). The furnace has an energy efficient ceramic fiber insulation package alone with 2″ long vestibules. The thermocouples are placed at the center of each zone. A ten-foot long power cable for each zone is provided to facilitate connection to the power source. A furnace is designed for horizontal or vertical operation and has the following specifications:

TABLE 1

| MODEL: | TV12-3x32-1/2Z |
|---|---|
| Maximum Temperature | 1200 degrees C. |
| Nominal Bore I.D. | 3 inches |
| Heated Length of Furnace | 32 inches |
| Furnace Outer Diameter Shell (approx) | 10-12 inches |
| Overall Furnace Length (approx.) | 36.25 inches |
| No. of Furnace Zones | 1 or 2 zones |
| Voltage (Nominal, 1 phase, 50/60 Hz.) | 208 volts |
| Total Power | 6,400 watts |

### Mellen Series PS205 Power Supply/Temperature Controller

One (1) Mellen Model PS205-208-(2)25-S, two zone, digital temperature controllers and solid state relay. The MELLEN Series PS205 consists of the following:

a.) Two (2) digital temperature controller calibrated for a Type “S” thermocouples featuring 126 segments & 31 programs.

b.) One (1) solid state relay.

c.) One (1) General Electric or equal circuit breaker, two pole, with appropriate-sized amperage rating.

d.) One (1) Mellen cabinet to house the above components.

e.) Two (2) Type “S” thermocouples including 10 ft. of compensated thermocouple extension wire, terminal boards, etc., per zone.

f.) All necessary wiring, terminal boards, interconnections, etc., to make a completely workable system.

### Over-temperature Protection for Power Supply/Temperature Controller

One (1) over-temperature (O.T.) alarm utilizing an independent digitally indicating, digital set-point “hi-limit alarm” controller. The O.T. Alarm package is furnished with an appropriate thermocouple, TIC extension wire, and sufficient mechanical power contactor(s) to interrupt power to the furnace in the event of an over-temperature condition at the location of the over-temperature sensor. The O.T. alarm option is mounted in the main temperature controller enclosure.

### Retort Model: RTA-2.5×32-OBE

One (1) Mellen Model RTA-2.5˜32-OBE, round, Hi-Purity Alumina retort to be used with the furnace described above. The retort working diameter is approximately 2.5 inches 1.D. by 32 inches. The retort has an O.D. of approximately 2.75″ inches and is 48″ inches long & contains the necessary stainless steel flange/seal assemblies, & heat shields to permit gas tight operation. Feedthroughs are provided in the cover plates of the retort for gas in/out and temperature measurement. The retort is capable of operating with different types of atmospheres.

While several embodiments of the invention have been described, it should be apparent, however, that various modifications, alterations and adaptations to those embodiments may occur to persons skilled in the art with the attainment of some or all of the advantages of the present invention. For example, in some embodiments of the present invention disclosed herein, a single component may be replaced by multiple components, and multiple components may be replaced by a single component, to perform a given function or functions. Except where such substitution would not be operative to practice embodiments of the present invention, such substitution is within the scope of the present invention. The disclosed embodiments are therefore intended to include all such modifications, alterations and adaptations without departing from the scope and spirit of the present invention as defined by the appended claims.

What is claimed is:

1. A method to apply a coating of Parylene to object, comprising the steps of:
A. vaporizing Parylene dimer by heating it to 150-200 degrees C. to form gaseous Parylene dimers;
B. cleaving gaseous Parylene dimers to gaseous Parylene monomers by heating gaseous Parylene dimers to 650 to 700 degrees C.;
C. vaporizing Silquest® by heating it to its evaporation point to form gaseous Silquest®;
D. contacting object to be coated with Parylene with the gaseous
Silquest® of Step C; and
E. contacting object to be coated with Parylene with the gaseous Parylene monomers of Step B for sufficient time to deposit coat of Parylene of a final thickness.

2. The method of claim 1, wherein the Parylene is selected from a group consisting of Parylene D, Parylene C, Parylene N, Parylene HT®, and a Parylene derived from Parylene N.

3. The method of claim 2, wherein the Parylene is Parylene C.

4. The method of claim 1, wherein in Step A, the Parylene dimer is vaporized by heating in two or more stages.

5. The method of claim 4, wherein the dimer is heated to about 170 degrees C., and then heated to about 200 degrees C. to about 220 degrees C.

6. The method of claim 1, wherein in Step B, the Parylene dimer is cleaved by heating in two or more stages.

7. The method of claim 6, wherein the Parylene dimer is heated to about 680 degrees C. and then to more than about 700 degrees C.

8. The method of claim 1, wherein in Steps C and D, the Silquest® is selected from the group consisting of Silquest® A-174, Silquest® 111 and Silquest® A-174(NT).

9. The method of claim 8, wherein the Silquest® is Silquest® A-174.

10. The method of claim 1, wherein in Step C, the Silquest® vaporized is in a 50:50 solution with water.

11. The method of claim 1, wherein in Step C the Silquest® is vaporized at 80 degrees C. for about 2 hours.

12. The method of claim 1, wherein the final thickness of the Parylene coat is from about 100 Angstrom to about 3.0 mm.

13. The method of claim 1, wherein the object to be coated with Parylene is incompatible with immersion in water.

14. The method of claim 1, wherein the object to be coated is selected from the group consisting of electronics equipment, paper, textiles, ceramics, plastics, frozen liquids, batteries, speakers, solid fuel, medical devices, paper, and space suits.

15. An object coated by the method of claim 1.

16. A method to coat objects with Silquest, comprising the steps:
A. vaporizing Silquest® by heating it to its evaporation point to form gaseous Silquest®; and
B. contacting object to be coated with Parylene with the gaseous
Silquest® of Step A.

17. The method of claim 16, wherein the Silquest® is selected from the group consisting of Silquest® A-174, Silquest® 111 and Silquest® A-174(NT).

18. The method of claim 17, wherein the Silquest® is Silquest® A-174.

19. The method of claim 16, wherein in Step A, the Silquest® vaporized is in a 50:50 solution with water.

20. The method of claim 16, wherein in Step A, the Silquest® is vaporized at 80 degrees C. for about 2 hours.

21. The method of claim 16, wherein the object to be coated with Parylene is incompatible with immersion in water.

22. The method of claim 16, wherein the object to be coated is selected from the group consisting of electronics equipment, paper, textiles, ceramics, plastics, frozen liquids, batteries, speakers, solid fuel, medical devices, paper, and space suits.

23. An object coated by the method of claim 16.

24. A polymer-coated object, comprising an object coated with Silquest® and with at least one polymer, wherein the object is incompatible with immersion in water.

25. The polymer-coated object of claim 24, wherein the uncoated object becomes at least partially non-functional after immersion in water and subsequent drying.

26. The polymer-coated object of claim 25, wherein the object is an electronics component.

27. The polymer-coated object of claim 24, wherein the uncoated object is degraded upon immersion in water.

28. The polymer-coated object of claim 27, wherein the object is selected from the group consisting of metal, paper and textile.

29. The polymer-coated object of claim 24, wherein the polymer is selected from the group consisting of polynaphtahlene (1,4-napthalene), diamine (O-tolidine), polytetrafluoroethylene (Teflon®), polyimides, silicas (SiO₂), titania (TiO₂), aluminum nitride (AlN), lanthanum hexaboride (LaB₆), Parylene D, Parylene C, Parylene N, Parylene HT®, and a Parylene derived from Parylene N.

30. The polymer-coated object of claim 29, wherein the polymer is Parylene C.

31. The polymer-coated object of claim 24, wherein the Silquest is selected from the group consisting of Silquest® A-174, Silquest® 111 and Silquest® A-174(NT).

32. The polymer-coated object of claim 31, wherein the Silquest® is Silquest® A-174.

33. The polymer-coated object of claim 25, wherein the polymer coating is on the inside and outside of the object.

34. The polymer-coated object of claim 33, wherein the polymer coating on the outside of the object is continuous with the polymer coating on the inside of the object.

35. An apparatus to apply a coating of Parylene, comprising
a vaporization chamber with a plurality of temperature zones; operably linked to
a pyrolysis chamber; operably linked to
a vacuum chamber.

36. The apparatus of claim 35, where the vacuum chamber is comprised of a deposition chamber operably linked to the pyrolysis chamber and a vacuum means.

37. The apparatus of claim 36, wherein the vacuum means is one or more vacuum pumps.

38. The apparatus of claim 35, wherein the vaporization chamber has a plurality of temperature zones.

39. The apparatus of claim 38, wherein the vaporization chamber has two temperature zones.

40. The apparatus of claim 35, wherein the vaporization chamber is a tubular furnace.

41. The apparatus of claim 35, wherein the pyrolysis chamber has a plurality of temperature zones.

42. The apparatus of claim 38, wherein the pyrolysis chamber has two temperature zones.

43. The apparatus of claim 35, wherein the pyrolysis chamber is a tubular furnace.
